(19) United States
(12) Patent Application Publication
(10) Pub. No.: US 2020/0217900 A1
(43) Pub. Date: Jul. 9, 2020

(54) Ascertaining the charge of a rechargeable battery

(71) Applicant: Hilti Aktiengesellschaft, Schaan (LI)

(72) Inventors: Klaus HAUSER, Schwabmuenchen (DE); David KOSCHECK, Augsburg (DE); Stefan MAYER, Dachau (DE)

(21) Appl. No.: 16/641,223

(22) PCT Filed: Aug. 14, 2018
(86) PCT No.: PCT/EP2018/071968

§ 371 Date: Feb. 21, 2020

(30) Foreign Application Priority Data
Aug. 23, 2017 (EP) 17187421.7

(51) Int. Cl. G01R 31/3828

(52) U.S. Cl. CPC G01R 31/3828

(57) ABSTRACT

A method for ascertaining a charge value for a system containing a power tool and a rechargeable battery used to supply the power tool with electrical energy. The method contains the method steps of detecting a first charge value of an electrical charge of the rechargeable battery at a first time instant; detecting a current value of an electric current flowing from the rechargeable battery to the power tool to supply the electrical load in the power tool, between a second time instant and third time instant (t₂, t₃); ascertaining a second charge value on the basis of the detected current value between a second time instant and third time instant; and subtracting the second charge value from the first charge value in order to ascertain a third charge value at the second time instant. Also provided is a rechargeable battery, power tool, and system containing a rechargeable battery and a power tool for performing the method.

The present invention relates to a method for ascertaining a charge value for a system containing a power tool and at least one rechargeable battery, said at least one rechargeable battery being used to supply the power tool with electrical energy.

The invention also relates to a rechargeable battery and to a power tool for performing the method. In addition, the present invention relates to a system containing at least one rechargeable battery and a power tool for performing the method.

### BACKGROUND

Cordless power tools can be operated with a rechargeable battery for the purpose of supplying power or energy. The cordless power tool may be, for example, a rechargeable battery-operated screwdriver, a hammer drill, or suchlike.

Rechargeable batteries usually contain a number of storage cells, or energy storage cells, for electrical energy. For the purpose of controlling a charging or discharging process of the storage cells, in which charging or discharging process the storage cells are either charged with electrical energy or electrical energy is drawn from the storage cells, modern rechargeable batteries have an electronic control system for closed-loop and open-looped control of various processes in the rechargeable battery. The storage cells are also known as rechargeable battery cells or secondary cells.

Usually for reasons of cost, rechargeable batteries according to the prior art do not have an apparatus for displaying to a user of a battery-operated power tool reliably at any given time the prevailing state of charge of, or the amount of energy still available from, the rechargeable battery.

Detecting as accurately as possible the prevailing state of charge, or the amount of energy or charge still stored in the rechargeable battery, however, allows the user to make a better assessment of whether planned tasks or jobs can still be completed in full using the battery-operated power tool with the residual charge of the rechargeable battery, or whether the rechargeable battery must be charged first.

### SUMMARY OF THE INVENTION

According to the prior art, it is already possible to ascertain the prevailing or actual state of charge (i.e. amount of charge or amount of energy) by measuring the no-load voltage of the rechargeable battery. This measurement, however, is only possible when the power tool is in an inoperative state, in which no electric current is flowing from the rechargeable battery to the power tool.

An object of the present invention is therefore to provide a method for ascertaining a charge value for a system containing a power tool and at least one rechargeable battery, said at least one rechargeable battery being used to supply the power tool with electrical energy.

It is also an alternate or additional object of the present invention to provide a rechargeable battery, a power tool, and a system containing at least one rechargeable battery and a power tool for performing the method that allows the aforementioned problem to be solved.

The present invention provides a method for ascertaining a charge value for a system containing a power tool and at least one rechargeable battery, said at least one rechargeable battery being used to supply the power tool with electrical energy.

According to the invention, the following steps are provided for the method:
detecting a first charge value of an electrical charge of the at least one rechargeable battery at a first time instant;
detecting a current value of an electric current flowing from the at least one rechargeable battery to the power tool to supply the electrical load in the power tool, between a first time instant and second time instant;
ascertaining a second charge value on the basis of the detected current value between the first time instant and second time instant; and
subtracting the second charge value from the first charge value in order to ascertain a third charge value at the second time instant.

Thereby, or especially by ascertaining the third charge value, it is possible to ascertain the prevailing or actual state of charge of the rechargeable battery reliably even while the battery-operated power tool is in use, i.e. when electric current is flowing from the rechargeable battery to the power tool, and the electric motor of the power tool is operating. Hence the user of the battery-operated power tool is always able to judge accurately the energy still stored in the rechargeable battery for forthcoming jobs.

According to an advantageous embodiment, it is also possible for the first charge value of an electrical charge of the at least one rechargeable battery to be stored in a non-volatile memory (NVM).

The time period between the first time instant and second time instant can also be referred to as the first time interval. The time period between the second time instant and the third time instant can also be referred to as the second time interval.

The present invention also provides a rechargeable battery, which can be connected to a power tool and which is configured to perform the method. Said rechargeable battery can contain a charge measuring apparatus for detecting a first charge value of an electrical charge in the rechargeable battery.

The present invention also provides a power tool for performing the method. Said power tool can contain a current measuring apparatus for detecting a current value of an electric current in the power tool flowing from the at least one rechargeable battery to the power tool to supply the electrical load in the power tool. The power tool can also contain a processor for ascertaining a second charge value on the basis of the detected current value between a first time instant and second time instant.

The present invention also provides a system containing at least one rechargeable battery and a power tool for performing the method.

Further advantages can be found in the description of the figures that follows. The FIGURES depict various exemplary embodiments of the present invention. The FIGURES, the description and the claims contain numerous features in combination. A person skilled in the art will expediently also consider the features individually and combine them to produce useful further combinations.

### BRIEF DESCRIPTION OF THE DRAWINGS

In the FIGURES:

FIG. 1 shows a sectional view of a power tool according to the invention comprising a rechargeable battery according to the invention, which is connected to the power tool.

### DETAILED DESCRIPTION

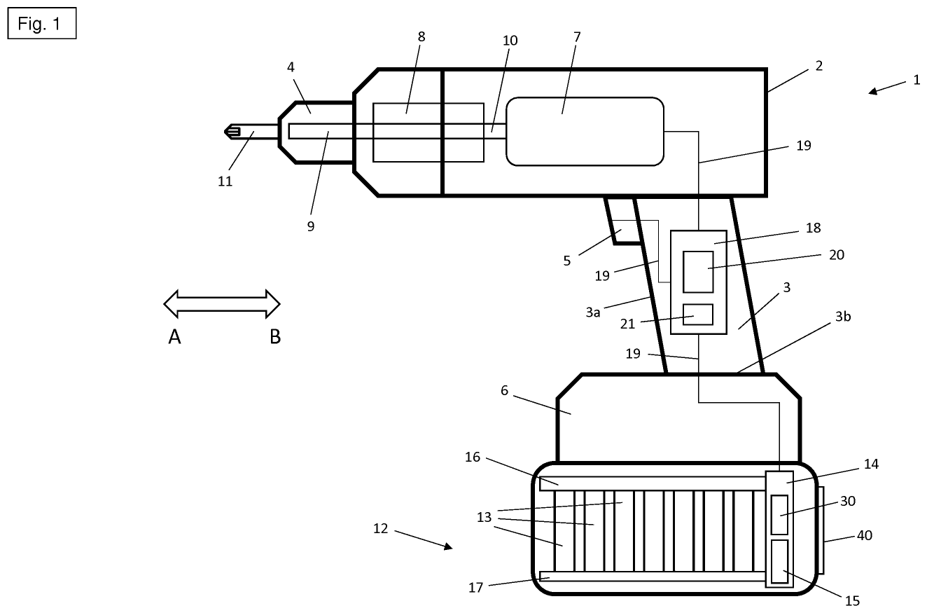

FIG. 1 depicts a power tool 1 according to the invention. The power tool 1 is designed, for example, in the form of a rechargeable battery-operated screwdriver and substantially contains a housing 2, a handle 3, a tool holder 4, an activation switch 5 and also a base part 6.

An electric motor 7, a gear mechanism 8, a drive shaft 9 and an output shaft 10 are positioned inside the housing 2. The electric motor 7 contains a rotatable rotor and a stator, and is connected to the gear mechanism 8 via the drive shaft 10. Neither the rotor nor the stator is shown in the FIGURE.

The gear mechanism 8 is further connected to the tool holder 4 by means of the drive shaft 9. The electric motor 7 serves to generate a torque which can be transmitted to the tool holder 4 by means of the output shaft 10, the gear mechanism 8 and the drive shaft 9. The tool holder 4 is positioned at a front end 2a of the housing 2 of the power tool 1. A tool 11, for example in the form of a screwdriver blade (also called a bit), can be received and held by the tool holder 4. The tool holder 4 transmits the torque from the drive shaft 9 to the tool 11 in the form of a bit in order to screw a screw into a material (e.g. wood). The material and the screw are not shown in the FIGURE.

The handle 3 is fastened to a lower end of the housing 2. The handle 3 has, in particular, a front side 3a and a lower end 3b. The activation switch 5 is positioned on the front side 3a. By means of the activation switch 5, a user of the power tool 1 can cause the electric motor 7, and hence the tool 11, to rotate.

Furthermore, the base part 6 is fastened to the lower end 3b of the handle 3. A rechargeable battery 12, for its part, is detachably positioned at a lower end 6a of the base part 6.

The rechargeable battery 12 is detachably connected to the power tool 1, and is used to supply electrical energy or electric current to the power tool 1. To this end, the rechargeable battery 12 contains substantially internally a number of energy storage cells 13 (also called rechargeable battery cells) and also a controller 14. The energy storage cells 13 and the controller 14 are connected to one another. Electrical energy or an electrical charge can be stored by means of the energy storage cells 13 and made available to a load.

The controller 14 of the rechargeable battery 12 in turn contains a charge measuring apparatus 15. The charge measuring apparatus 15 is used to detect a first charge value of an electrical charge stored in the energy storage cells 13. Said first charge value equals the electrical charge available in the energy storage cells 13 at a specific time instant.

The individual energy storage cells 13 are mechanically and electrically connected to the controller 14 by means of an upper and a lower cell holder 16, 17, so that electrical energy or electric current can flow from the individual energy storage cells 13 to the controller 14. The charge measuring device 15 contained in the controller 14 measures at time intervals, i.e. at specific time instants apart, the electrical charge still stored in the energy storage cells 13. The values of the measured electrical charge are stored in a non-volatile memory 30.

A control apparatus 18 for the power tool 1 is provided inside the handle 3. The control apparatus 18 is connected to the electric motor 7, to the activation switch 5 and also to the controller 14 of the rechargeable battery 12 via respective lines 19. Said lines 19 are used to transfer signals and electric current.

By moving the activation switch 5 in direction B, a signal can be sent from the activation switch 5 to the control apparatus 18, as a result of which the control apparatus 18 in turn sends a signal to the controller 14 of the rechargeable battery 12. As a result of the signal sent to the controller 14, electrical energy or electric current at a specific current value is sent from the energy storage cells 13 to the electrical loads of the power tool 1 and in particular to the electric motor 7. In order to send a signal to the control apparatus 18 in accordance with the travel of the activation switch 5 in direction B, the activation switch 5 contains a potentiometer (not shown).

If the activation switch 5 moves again in direction A, a corresponding signal is sent to the control apparatus 18 by means of the potentiometer, so that no more electrical charge or electric current flows from the energy storage cells 13 to the power tool 1.

The control apparatus 18 also contains a current measuring device 20 and a processor 21.

The current measuring apparatus 20 is used to detect a current value of an electric current flowing from the energy storage cells 13 to the power tool 1 to supply the electrical load, in particular electric motor 7, in the power tool 1. Said detection or measurement of the current value takes place between a first time instant t₁ and second time instant t₂ for a specific time length or for a specific time interval.

In order to perform the method according to the invention, the prevailing electrical charge Q(t₁) in the energy storage cells 13 is first detected at a specific first time instant t₁. The charge measuring apparatus 15 in the rechargeable battery 12 is used to perform said detection or measurement of the charge Q(t₁). The value of the prevailing electrical charge Q(t₁) is stored in the memory 30. In this case, also a plurality of values of the electrical charge can be stored systematically in the memory 30. The controller 14 of the rechargeable battery 12 sends the value of the prevailing electrical charge Q(t₁) via the line 19 to the control apparatus 18 of the power tool 1.

If the power tool 1 is in use, i.e. is being operated by means of the activation switch 5 of the electric motor 7, electric current flows from the energy storage cells 13 to the electric motor 7 via the controller 14 of the rechargeable battery 12, the line 19, and the control apparatus 18 of the power tool 1. The electric current can set the rotor (not shown) of the electric motor 7 in rotary motion in order to produce thereby a torque for the tool 11.

The current measuring apparatus 20 of the control apparatus 18 detects the amount of electric current that flows in a first time interval, i.e. between a first time instant t₁ and second time instant t₂, from the energy storage cells 13 through the controller 14 and finally to the electric motor 7. Using the equations:

Q=I×t

Q(t₃)=Q(t₁)−∫ₜ_{₁}^{t}^{₂}I(t)dt

where

Q (t₃)=total electrical charge remaining in the energy storage cells 13 at the third time instant;

Q (t₁)=prevailing electrical charge in the energy storage cells 13 at the first time instant;

I=current in amperes (A or mA)

t=time

t₁ to t₂=time interval between a first time instant and second time instant,

the processor 21 ascertains the electrical charge as the integral over the time interval, i.e. between the first time instant t₁ and the second time instant t₂, of the electric current that flows in order to supply the electrical load in the power tool 1.

Ascertaining the electrical charge makes use of the fact that the integral of the electric current over time represents the charge that has flowed into, or through, a body.

The control apparatus 18 sends via the lines 19 to the controller 14 of the rechargeable battery 12, the value of the electrical charge ascertained in the power tool 1. In the controller 14 of the rechargeable battery 12, the value of the ascertained charge (i.e. the integral over time of the electric current that has flowed) is deducted (subtracted) from the detected charge Q(t₁), thereby ascertaining the electrical charge Q (t₃) still actually stored in the energy storage cells 13 at the time instant t₃.

The ascertained electrical charge Q(t₃) currently still available at the time instant t₃ can be displayed on a display apparatus 40 on the rechargeable battery 12. The user of the power tool 1 is hence informed of how much electrical energy is actually still available from the rechargeable battery 12.

According to a further embodiment (not shown in the FIGURES), it is also possible that the display apparatus 40 for displaying the ascertained electrical charge Q(t₃) currently still available in the energy storage cells 13 at the time instant t₃ is positioned on the power tool 1.

In addition, according to a further embodiment (not shown in the FIGURES), it is also possible that the display of the ascertained electrical charge Q(t₃) currently still available in the energy storage cells 13 at the time instant t₃ is sent to an external display apparatus by means of a wireless connection. For example, the external display apparatus may be augmented-reality glasses, a smartphone or suchlike.

Furthermore, according to the method described above, it is also possible that the charge ascertained in the power tool 1 is the integral of the electric current that is consumed during an application, i.e. from the start to the end of an application.

An application here means an actual work process using a corresponding power tool 1, for instance a process such as drilling a hole, screwing in a screw, sawing a certain length of a material, or suchlike. By ascertaining the electrical charge that is needed for a specific application or a specific work process, it is possible to ascertain and display the number of applications that can still be carried out using the electrical charge Q(t₃) actually present in the energy storage cells 13.

1-4. (canceled)

5. A method for ascertaining a charge value for a system including a power tool and at least one rechargeable battery used to supply the power tool with electrical energy, the method comprising the steps of:
detecting a first charge value of an electrical charge of the at least one rechargeable battery at a first time instant;
detecting a current value of an electric current flowing from the at least one rechargeable battery to the power tool to supply an electrical load in the power tool, between a first time instant and second time instant;
ascertaining a second charge value on the basis of the detected current value between the first time instant and second time instant; and
subtracting the second charge value from the first charge value in order to ascertain a third charge value at the second time instant.

6. A rechargeable battery connectable to a power tool, for performing the method as recited in claim 5, and comprising:
a charge measurer for detecting the first charge value of the electrical charge in the rechargeable battery.

7. A power tool connectable to a rechargeable battery, for performing the method as recited in claim 5, and comprising:
a current measurer for detecting the current value of the electric current in the power tool flowing from the at least one rechargeable battery to the power tool to supply the electrical load in the power tool, and
a processor for ascertaining a second charge value on the basis of the detected current value between a first time instant and second time instant.

8. A system comprising at least one rechargeable battery and a power tool for performing the method as recited in claim 5.
